(19) United States
(12) Patent Application Publication
(10) Pub. No.: US 2006/0220163 A1
(43) Pub. Date: Oct. 5, 2006

(54) Light sources that use diamond nanowires

(76) Inventors: Shih-Yuan Wang, Palo Alto, CA (US); M. Saif Islam, Mountain View, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/096,949

(22) Filed: Mar. 31, 2005

(51) Int. Cl. H01L 27/14

(52) U.S. Cl. 257/431

(57) ABSTRACT

Light sources that use diamond nanowires, and methods of forming the same, are described. For example, the light source can include a diamond nanowire that bridges the gap between a first electrode and a second electrode to electrically couple the two electrodes. A power source coupled to the first and second electrodes forms a circuit. The diamond nanowire emits light with the power source turned on.

### TECHNICAL FIELD

Embodiments of the present invention relate to nanotechnology.

### BACKGROUND ART

A type of conventional light source employs tungsten wires as filaments. The tungsten wires project light when heated by passing an electrical current through them.

Tungsten is a lossy material for visible wavelengths of light; this can cause high attenuation in the generated light. The tungsten wires may be layered in overlapping fashion in an arrangement sometimes referred to as a three-dimensional metallic crystal or a three-dimensional tungsten photonic crystal. Because tungsten is opaque, a layer of tungsten wire may block at least some of the light projected by another layer of tungsten wire. Thus, the amount of light projected from a tungsten light source is less than the amount of light actually produced.

Accordingly, a more efficient light source would be advantageous.

### DISCLOSURE OF THE INVENTION

Embodiments in accordance with the present invention pertain to light sources that use diamond nanowires to generate light, and methods of forming the same. In one embodiment, a light source includes a diamond nanowire that bridges the gap between a first electrode and a second electrode to electrically couple the two electrodes. A power source coupled to the first and second electrodes forms a circuit. The diamond nanowire emits light with the power source turned on.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 illustrates one embodiment of a light source using diamond nanowires in accordance with the present invention.

FIG. 2 illustrates another embodiment of a light source using diamond nanowires in accordance with the present invention.

FIG. 3 is a flowchart of one embodiment of a method for forming a light source in accordance with the present invention.

FIG. 4 illustrates a stage in the forming of a light source according to the method of FIG. 3.

FIG. 5 illustrates another stage in the forming of a light source according to the method of FIG. 3.

FIG. 6 illustrates another stage in the forming of a light source according to the method of FIG. 3.

FIG. 7 is a flowchart of another embodiment of a method for forming a light source in accordance with the present invention.

FIG. 8 illustrates a stage in the forming of a light source according to the method of FIG. 7.

FIG. 9 illustrates another stage in the forming of a light source according to the method of FIG. 7.

FIG. 10 is a flowchart of another embodiment of a method for forming a light source in accordance with the present invention.

FIG. 11 illustrates a stage in the forming of a light source according to the method of FIG. 10.

FIG. 12 illustrates another stage in the forming of a light source according to the method of FIG. 10.

The drawings referred to in this description should not be understood as being drawn to scale except if specifically noted.

### BEST MODE FOR CARRYING OUT THE INVENTION

Reference will now be made in detail to various embodiments of the invention, examples of which are illustrated in the accompanying drawings. While the invention will be described in conjunction with these embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following description of the present invention, numerous specific details are set forth in order to provide a thorough understanding of the present invention. In other instances, well-known methods, procedures, components, and circuits have not been described in detail as not to unnecessarily obscure aspects of the present invention.

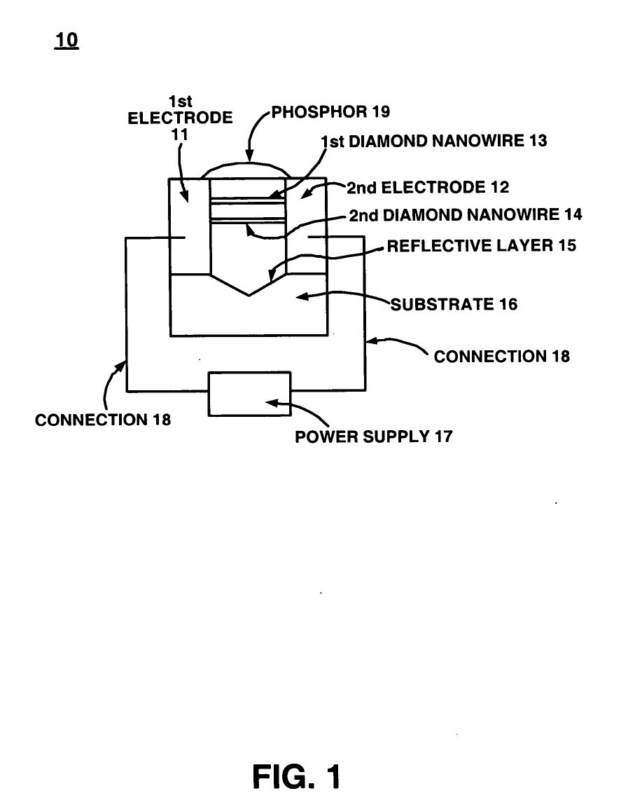

FIG. 1 illustrates one embodiment of a light source 10 in accordance with the present invention. A single light source 10 is illustrated in FIG. 1; however, multiples of light source 10 may be used together.

In the example of FIG. 1, light source 10 includes a first electrode 11 and a second electrode 12 separated by a gap. In one embodiment, the distance between the first and second electrodes 11 and 12 is less than approximately ten microns. The gap is bridged by a first diamond nanowire 13 and a second diamond nanowire 14. In practice, there may be many diamond nanowires that bridge the gap between the two electrodes. In one embodiment, the nanowires 13 and 14 have a diameter of less than approximately 100 nanometers.

In one embodiment, a first portion of each of the diamond nanowires 13 and 14 is doped with a p-type dopant (e.g., boron), and a second portion of each of the diamond nanowires 13 and 14 is doped with an n-type dopant (e.g., phosphorous), thereby forming a p-n junction in each diamond nanowire.

In one embodiment, the first electrode 11 and the second electrode 12 are electrically separated by a substrate 16 doped with an insulating material. Alternatively, light source 10 may utilize a silicon-on-insulator (SOI) structure, in which the electrodes are separated from the substrate 16 (e.g., a silicon substrate) by a layer of silicon dioxide. In general, the first electrode 11 and the second electrode 12 are electrically isolated from each other.

In one embodiment, light source 10 includes a reflective layer 15 situated on the substrate 16 and perhaps extending along the sides of the first and second electrodes 11 and 12. The reflective layer 15 may be a nonmetallic (e.g., dielectric) material so that electrical isolation of the first and second electrodes 11 and 12 is maintained. Alternatively, a metallic material may be used for reflective layer 15, with the metallic material applied so that electrical isolation of the first and second electrodes 11 and 12 is maintained.

The first and second electrodes 11 and 12 are coupled to a power supply 17 by connection 18. With power supply 17 turned on, a current is passed between the first and second electrodes 11 and 12 through the first and second diamond nanowires 13 and 14. As mentioned above, in one embodiment, there is a p-n junction in each of the first and second diamond nanowires 13 and 14. At a forward bias of about 20 volts, the diamond nanowires 13 and 14 emit ultraviolet (UV) light with peak luminescence appearing at about 235 nanometers.

In alternate embodiments, without a p-n junction in the diamond nanowires 13 and 14, light can be emitted using optical excitation, or if the diamond nanowires are electrically energized, then light is emitted using thermionic emission by resistive heating.

In one embodiment, the light emitted by diamond nanowires 13 and 14 is received onto a phosphor 19. For example, a phosphor material can be placed across the opening of the gap between the first and second electrodes 11 and 12, as illustrated in FIG. 1. If the light emitted by light source 10 is UV light, the phosphor 19 is excited by the UV light and emits light in the visible spectrum. Different colors of phosphors can be used to produce visible light of virtually any color, including white.

Significantly, diamond nanowires 13 and 14 are transparent. Thus, for example, light emitted by diamond nanowire 14 is transmitted through diamond nanowire 13. As mentioned above, there may be many diamond nanowires in light source 10. There may also be many layers of diamond nanowires; the layers may be intertwined, and individual nanowires may be entwined with other nanowires. By virtue of the transparency of the diamond nanowires, light generated by the mass of nanowires and with energy below the bandgap of diamond is more efficiently transmitted through and hence out of the mass.

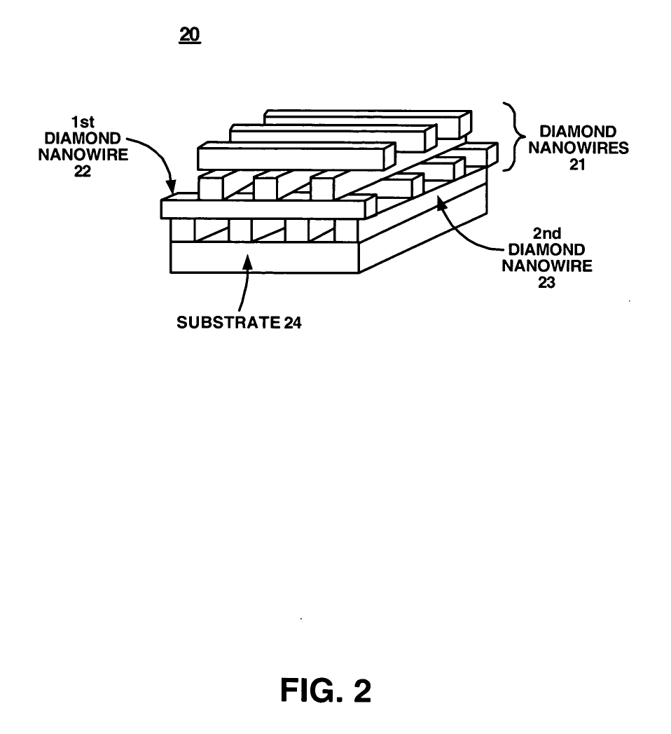

FIG. 2 illustrates one embodiment of a light source 20 in accordance with the present invention. A single light source 20 is illustrated in FIG. 2; however, multiples of light source 20 may be used together.

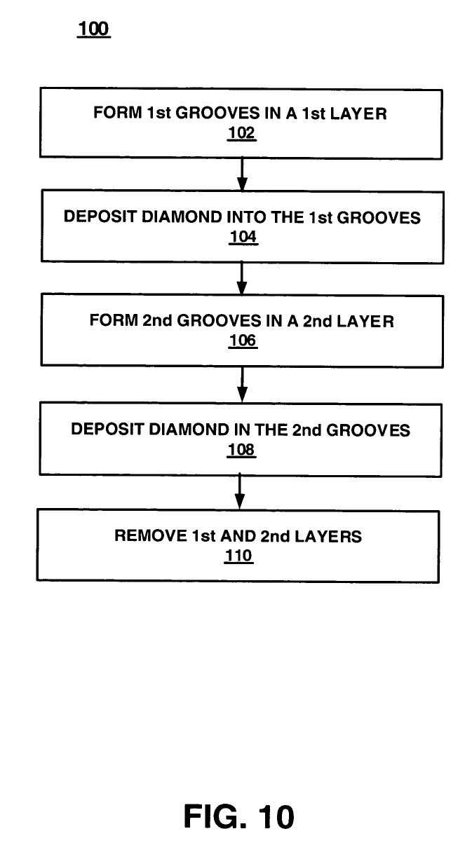

In the example of FIG. 2, a number of diamond nanowires 21 (exemplified by first and second diamond nanowires 22 and 23) are formed in layers on a substrate 24. In one embodiment, the diamond nanowires in a layer are substantially parallel to each other, and the diamond nanowires in one layer are substantially perpendicular to the diamond nanowires in an adjacent layer. Thus, for example, first diamond nanowire 22 is substantially parallel to other diamond nanowires that are in the same layer as diamond nanowire 22, and first diamond nanowire 22 is substantially perpendicular to second diamond nanowire 23. As will be described further below, this arrangement is a result of the process used to form light source 20 (see FIGS. 10, 11 and 12); other arrangements are possible.

The light source 20 can be coupled to a power source (not shown). In one embodiment, electrodes can be coupled to any of the edges of light source 20; however, the distance between the electrodes affects heat and current distribution in light source 20, and thus in one embodiment the electrodes are coupled to diagonally opposite edges of the light source, as this provides the greatest distance between the electrodes. Because the diamond nanowires are in contact with each other, when the power supply is turned on, light is emitted from thermionic emission through resistive heating.

In another embodiment, one layer of nanowires is doped with p-type of dopant, the next layer with n-type dopant, the next layer with p-type dopant, and so on, thus providing alternating layers of p-doped nanowires and n-doped nanowires. P-n junctions are formed at the points at which nanowires in one layer cross (and thus connect with) nanowires in another layer. These p-n junctions will emit light when the power supply is turned on. In one embodiment, electrodes are coupled to opposite ends of the nanowires.

By virtue of the transparency of the diamond nanowires, light generated by one layer of nanowires is efficiently transmitted through any overlapping layers of nanowires.

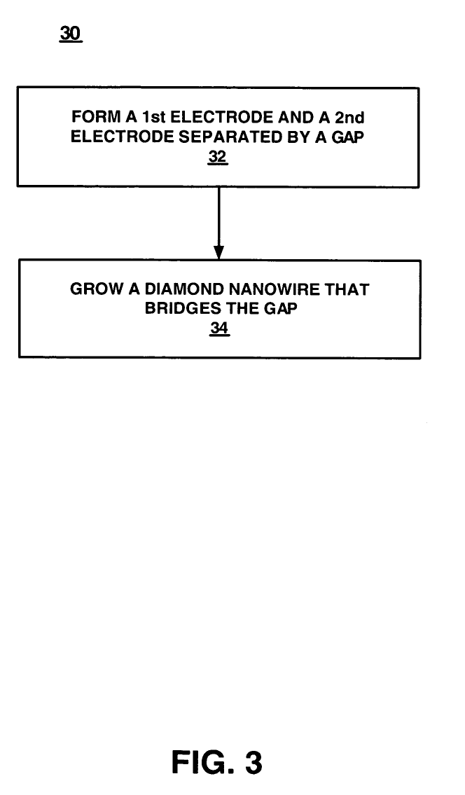

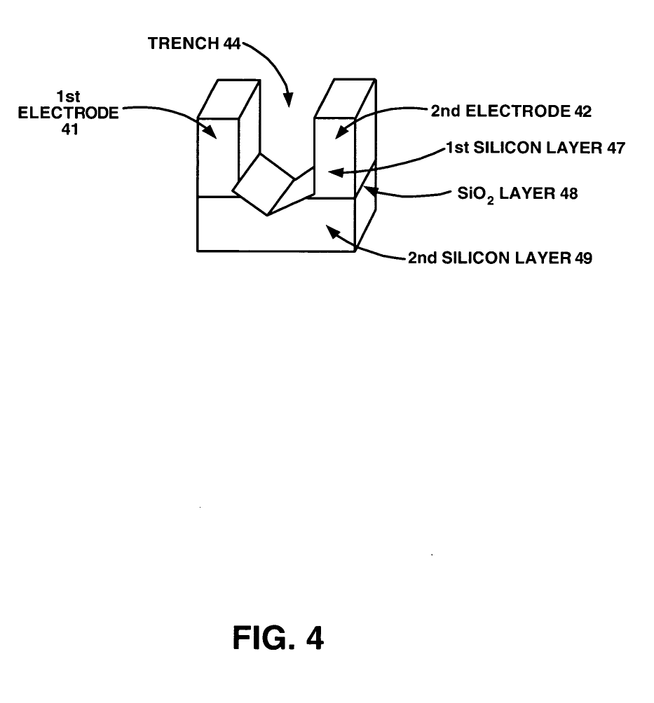

FIG. 3 is a flowchart 30 of one embodiment of a method for forming a light source (e.g., light source 10 of FIG. 1) in accordance with the present invention. Although specific steps are disclosed in flowchart 30, such steps are exemplary. Also, various other steps or variations of the steps recited in flowchart 30 may be performed. FIG. 3 is described in conjunction with FIGS. 4, 5 and 6, which illustrate various stages in the forming of the light source 10.

In step 32 of FIG. 3, with reference also to FIG. 4, a first electrode 41 and a second electrode 42 are formed. In one embodiment, the first and second electrodes 41 and 42 are formed from an SOI structure, in which a layer 48 of silicon dioxide (SiO₂) separates a first layer 47 of silicon and a second layer 49 of silicon. The trench 44 is etched (e.g., using anisotropic wet chemical etching) through the first layer 47 of silicon, down to the layer 48 of silicon dioxide, thereby removing the entire thickness of the first layer 47 of silicon between the electrodes being formed. In essence, the first layer 47 of silicon is formed into two columns as illustrated in FIG. 4; the columns sit atop a layer 48 of silicon dioxide, with no silicon connecting the two columns. The first and second electrodes 41 and 42 are thus formed from silicon layer 47 and electrically isolated from each other by the layer 48 of silicon dioxide.

The sidewalls of trench 44 are substantially parallel to each other. One side of the trench 44 can be doped with a p-type dopant and the other side with an n-type dopant.

Alternatively, trench 44 can be formed by etching a substrate (e.g., a silicon substrate). To electrically isolate the first electrode 41 from the second electrode 42, an insulating material can be added to the substrate between the two electrodes.

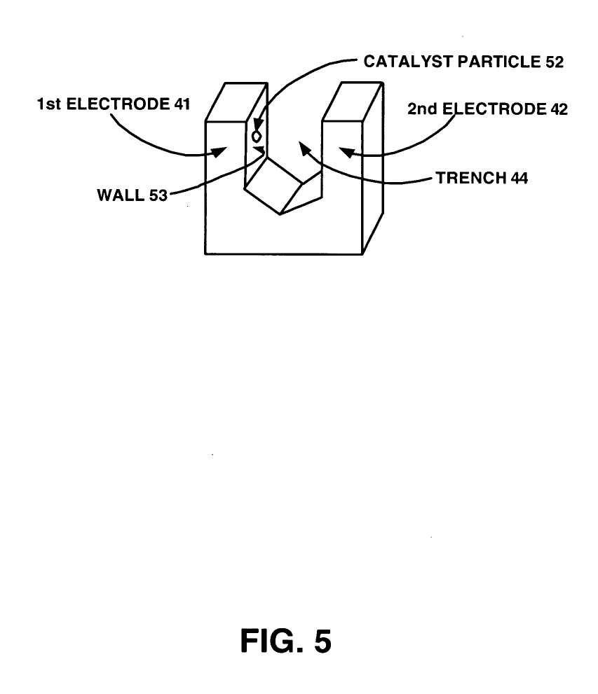

In step 34, with reference also to FIG. 5, a diamond nanowire is grown across the gap between the first and second electrodes 41 and 42. In one embodiment, a thin layer of a catalyst is deposited on at least one of the walls (e.g., wall 53) of the electrodes 41 and 42. The catalyst may be metallic, such as gold or titanium. Catalyst deposition on the area between the electrodes 41 and 42 (e.g., at the bottom of trench 44) is avoided, or any catalyst deposited on the area between the electrodes 41 and 42 is removed. The catalyst is then annealed to form isolated nanoparticles of the catalyst material (e.g., catalyst particle 52).

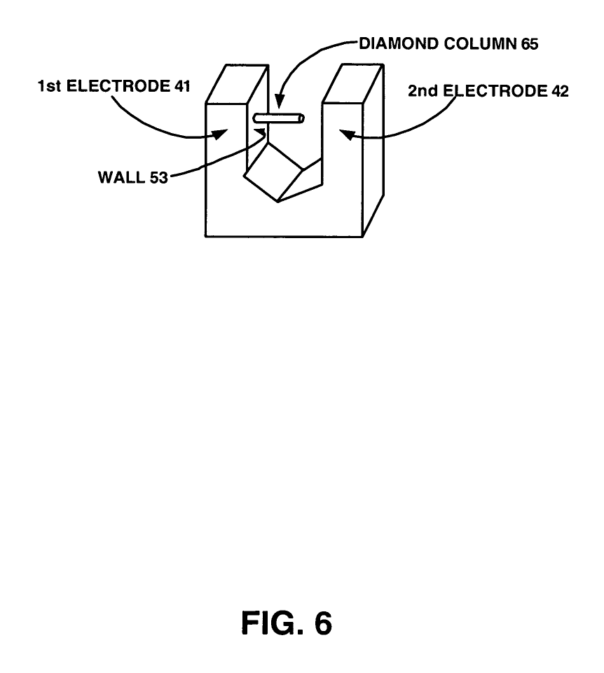

With reference now to FIG. 6, the catalyst is then exposed to diamond nanoparticles. In one embodiment, the diamond particles are diffused around the wall 53 using plasma chemical vapor deposition (CVD). Alternatively, metal-organic chemical vapor deposition (MOCVD) can be used. The diamond nanoparticles are precipitated on the wall 53 of the first electrode 41 in the area of the catalyst particle 52 (FIG. 5). Specifically, the diamond particles diffuse around the catalyst particle 52 and precipitate on the underlying substrate. Continued precipitation at the diamond-catalyst interface pushes the catalyst particle 52 from the surface, forming diamond column 65. The catalyst particle 52 remains at the tip of the growing diamond column 65. The growing nanowire has a diameter similar to that of the catalyst particle at the tip of the column. The diamond column 65 can continue to grow in this manner until it makes contact with the second electrode 41, thereby forming a diamond nanowire (e.g., diamond nanowire 13 or 14 of FIG. 1) that bridges the gap between the first and second electrodes 41 and 42.

The diamond nanowire can be doped with p-type or n-type dopant materials as the nanowire is grown so that the formed nanowire includes a p-n junction. For example, the diamond column 65 can be exposed to p-type dopant material during its earlier period of growth, then to n-type dopant material during its later period of growth. Alternatively, after the diamond column 65 has finished growing to form a diamond nanowire, one portion of the diamond nanowire can be implanted with p-type dopant and another portion with n-type dopant. As mentioned above, the intent is to form a p-n junction in the diamond nanowire that is grown across the gap between the first and second electrodes 41 and 42.

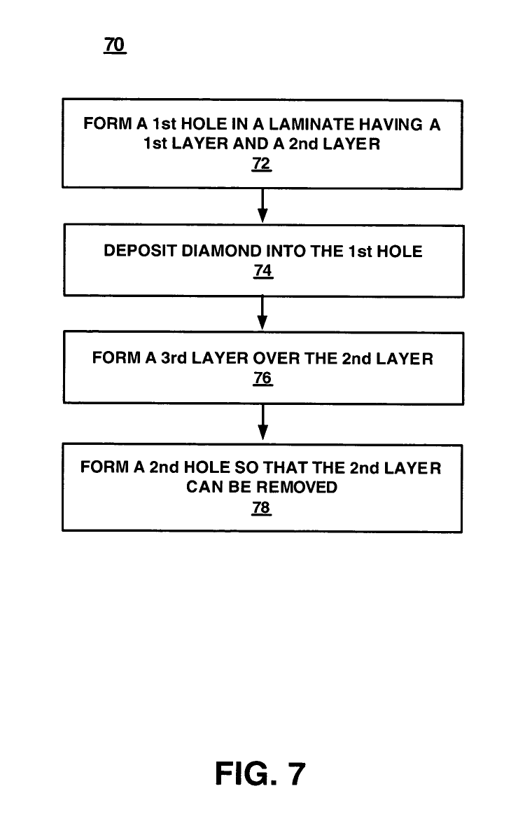

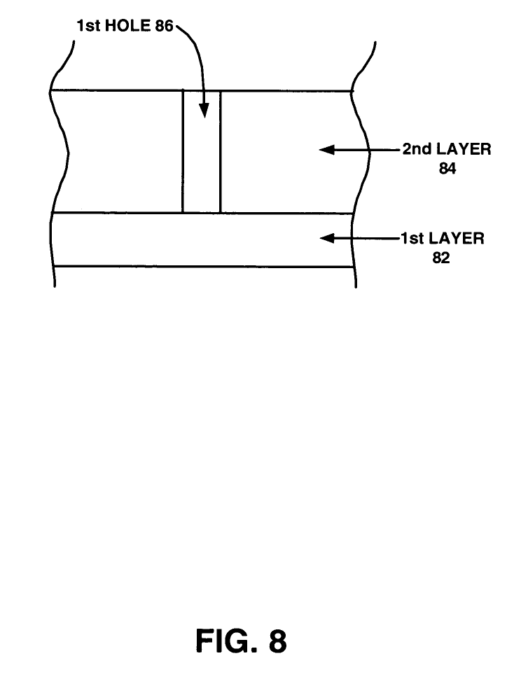

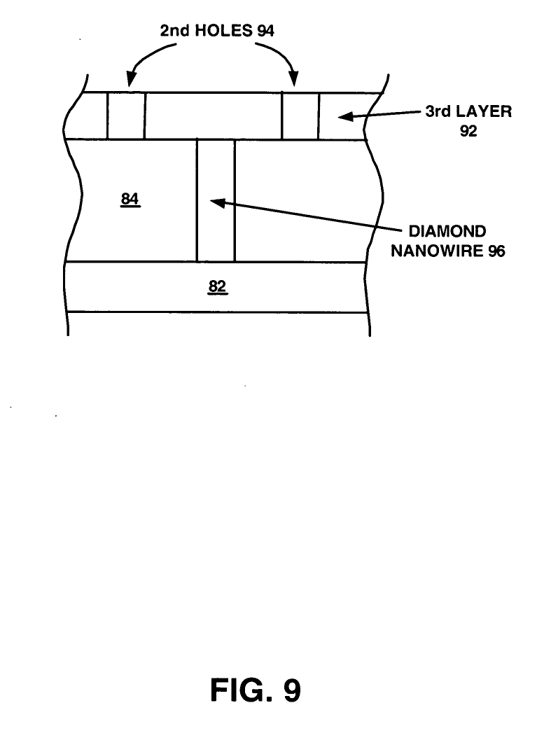

FIG. 7 is a flowchart 70 of another embodiment of a method for forming a light source (e.g., light source 10 of FIG. 1) in accordance with the present invention. Although specific steps are disclosed in flowchart 70, such steps are exemplary. Also, various other steps or variations of the steps recited in flowchart 70 may be performed. FIG. 7 is described in conjunction with FIGS. 8 and 9, which illustrate various stages in the forming of the light source 10.

In step 72 of FIG. 7, with reference also to FIG. 8, a first hole 86 is formed in a laminate that includes a first layer 82 and a second layer 84. Various techniques can be used to form the laminate. In one embodiment, layer 82 is a silicon substrate, and layer 84 is a material such as aluminum oxide (Al₂O₃). In essence, the first and second layers 82 and 84 and the hole 86 serve as a template for forming a diamond nanowire. A single hole 86 is shown; in actual practice, there may be many such holes.

In step 74 of FIG. 7, with reference also to FIG. 8, the hole 86 is filled with diamond nanoparticles to form a diamond nanowire 96 (FIG. 9). In one embodiment, the first layer 82 is heated, in essence causing the diamond nanoparticles to clump together to form a nanowire.

If hole 86 is overfilled, then chemical-mechanical polishing (CMP) can be performed to remove any excess diamond fill that is protruding from hole 86.

The first layer 82 is doped with either a p-type dopant or an n-type dopant. In one embodiment, as the hole 86 is filled with diamond, the diamond fill is first doped with one type of dopant (the dopant type that matches that of layer 82), and then with another type of dopant. For example, if layer 82 is doped with a p-type dopant, the diamond fill being placed into hole 86 is doped with a p-type dopant up to a point, then as the diamond fill continues to be added into hole 86, a switch is made to an n-type dopant. As noted previously herein, the intent is to form a p-n junction in the diamond nanowire 96.

In step 76 of FIG. 7, with reference also to FIG. 9, a third layer 92 is formed over the second layer 84. Various techniques can be used to form the third layer 92. In one embodiment, third layer 92 is a silicon substrate that is doped with either a p-type dopant or an n-type dopant, depending on the dopant implanted in the first layer 82 (for example, if first layer 82 is doped with a p-type dopant, then third layer 92 is doped with an n-type dopant).

In step 78 of FIG. 7, with reference also to FIG. 9, second holes 94 are formed in one of the outer layers (e.g., in third layer 92), allowing access to the second layer 84 so that the second layer 84 can be removed (e.g., etched out). After removal of the second layer 84, diamond nanowire 96 remains, bridging the distance between the first and third layers 82 and 92. Diamond nanowires formed in this manner are demonstrated to have sufficient strength to remain intact once layer 84 is removed. The first and third layers 82 and 92 are analogous to the first and second electrodes 11 and 12 of FIG. 1, and the diamond nanowire 96 is analogous to diamond nanowire 13 or 14 of FIG. 1.

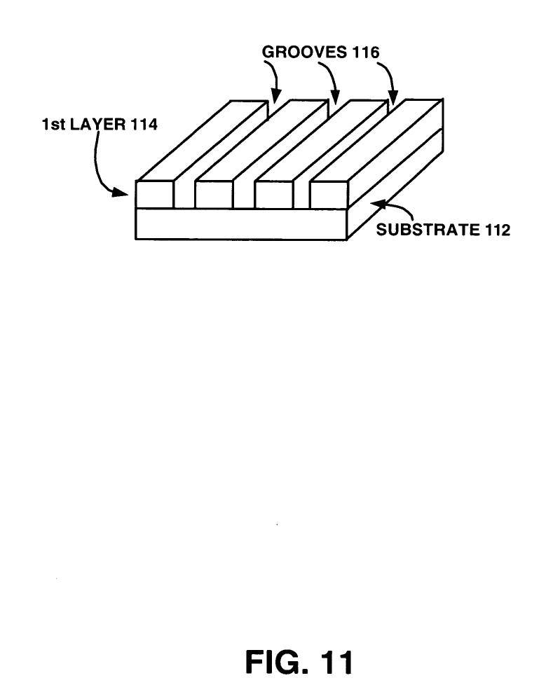

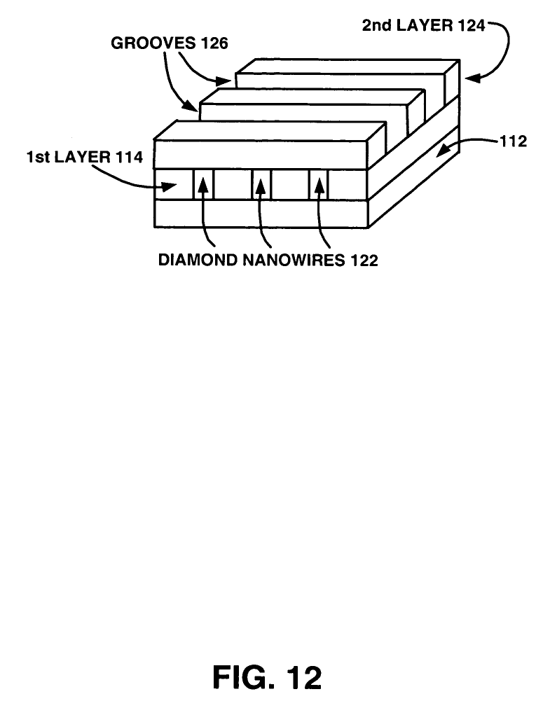

FIG. 10 is a flowchart 100 of another embodiment of a method for forming a light source (e.g., light source 20 of FIG. 2) in accordance with the present invention. Although specific steps are disclosed in flowchart 100, such steps are exemplary. Also, various other steps or variations of the steps recited in flowchart 100 may be performed. FIG. 10 is described in conjunction with FIGS. 11 and 12, which illustrate various stages in the forming of the light source 20.

In step 102 of FIG. 10, with reference also to FIG. 11, a first layer 114 is formed on a substrate 112 (e.g., a silicon substrate or an SOI structure). Various techniques can be used to form first layer 114 on substrate 112. Using familiar techniques, multiple grooves 116 are then formed in layer 114. The grooves 116 are substantially parallel to each other.

In step 104 of FIG. 10, with reference also to FIG. 11, the grooves 116 are then filled with diamond nanoparticles to form diamond nanowires 122 (FIG. 12). In one embodiment, the layer 114 is heated, in essence causing the diamond nanoparticles to clump together to form a nanowire.

In one embodiment, one portion of the diamond can be doped with a p-type dopant and another portion with an n-type dopant to form a p-n junction in each diamond nanowire. In another embodiment, the diamond is doped only with one type of dopant (either p-type or n-type). If the grooves 116 are overfilled, then CMP can be used to remove any excess diamond fill that is protruding from the grooves 116.

In step 106 of FIG. 10, with reference also to FIG. 12, a second layer 124 is formed over the first layer 114 and diamond nanowires 122. Various techniques can be used to form the second layer 124. Multiple grooves 126 can then be formed in layer 124. In one embodiment, the grooves 126 are substantially parallel to each other, and substantially perpendicular to the diamond nanowires 122. The grooves 126 are filled with diamond to form a second layer of diamond nanowires. In one embodiment, the layer 124 is heated, in essence causing the diamond nanoparticles to clump together to form a nanowire. As mentioned above, one portion of the diamond can be doped with a p-type dopant and another portion with an n-type dopant to form a p-n junction in each diamond nanowire. Alternatively, the diamond is doped only with one type of dopant—if the nanowires of first layer 114 are doped with p-type dopant, for example, then the nanowires of second layer 124 are doped with n-type dopant, to form alternating layers of p-doped nanowires and n-doped nanowires. CMP can be used to remove excess diamond fill protruding from the grooves 126. The process of flowchart 100 can then be repeated to form additional layers of diamond nanowires.

In the examples discussed above, the diamond nanowires are described as having p-n junctions that are used for electrical excitation. Diamond nanowires can emit light without the presence of p-n junctions if optical excitation is used instead. Alternatively, if the diamond nanowires are electrically energized, thermionic emission by resistive heating also results in light being emitted without the presence of p-n junctions.

Embodiments of the present invention are thus described. While the present invention has been described in particular embodiments, it should be appreciated that the present invention should not be construed as limited by such embodiments, but rather construed according to the following claims.

What is claimed is:

1. A light source comprising:
a first electrode and a second electrode separated by a gap;
a diamond nanowire that bridges said gap to electrically couple said first and second electrodes; and
a power source coupled to said first and second electrodes to form a circuit, wherein said diamond nanowire emits light with said power source turned on.

2. The light source of claim 1 wherein a first portion of said diamond nanowire is doped with p-type dopant and a second portion of said diamond nanowire is doped with n-type dopant to form a p-n junction in said diamond nanowire.

3. The light source of claim 1 wherein said light is ultraviolet light.

4. The light source of claim 1 wherein said light is emitted onto a phosphor.

5. The light source of claim 1 disposed on a substrate comprising a reflective layer.

6. The light source of claim 1 wherein said gap is less than approximately ten microns.

7. The light source of claim 1 wherein said diamond nanowire has a diameter of less than approximately 100 nanometers.

8. A light source comprising:
a plurality of diamond nanowires arranged in multiple layers, wherein diamond nanowires in a layer are substantially parallel to each other and wherein diamond nanowires in neighboring layers are substantially perpendicular to each other; and
a power source coupled to said diamond nanowires to form a circuit, wherein said diamond nanowires emit light with said power source turned on.

9. The light source of claim 8 wherein diamond nanowires in a first layer are doped with p-type dopant and diamond nanowires in a second layer adjacent said first layer are doped with n-type dopant to form p-n junctions where said diamond nanowires in said first layer cross said diamond nanowires in said second layer.

10. The light source of claim 8 wherein said light is ultraviolet light.

11. The light source of claim 8 wherein said light is emitted onto a phosphor.

12. The light source of claim 8 disposed on a substrate comprising a reflective layer.

13. A method of forming a light source, said method comprising:
forming a first electrode and a second electrode separated by a gap; and
growing a diamond nanowire from said first electrode across said gap to said second electrode, wherein said diamond nanowire emits light with said first and second electrodes coupled to a power source.

14. The method of claim 13 further comprising:
forming a trench in a substrate, wherein a first wall of said trench comprises said first electrode and a second wall of said trench comprises said second electrode;
depositing a catalyst on at least said first wall; and
introducing a substance comprising diamond to said trench, said diamond forming a column that grows from said first wall to form said diamond nanowire.

15. The method of claim 14 further comprising implanting a first dopant material, then a second dopant material into said column as said column is grown to form a p-n junction.

16. The method of claim 13 further comprising implanting a p-type dopant into a first portion of said diamond nanowire and an n-type dopant into a second portion of said diamond nanowire to form a p-n junction in said diamond nanowire.

17. The method of claim 13 wherein said gap is less than approximately ten microns.

18. The method of claim 13 wherein said diamond nanowire has a diameter of less than approximately 100 nanometers.

19. A method of forming a light source, said method comprising:
forming a first hole in a laminate comprising a first layer and a second layer, said first hole extending through said second layer to expose said first layer;
depositing diamond into said first hole;
forming a third layer over said second layer including the area of said first hole; and
forming a second hole in at least one of said first and third layers, said second hole allowing removal of said second layer to form a diamond nanowire that extends from said first layer to said third layer, wherein said diamond nanowire emits light when coupled to a power source.

20. The method of claim 19 wherein a first portion of said diamond nanowire includes p-type dopant and a second portion of said diamond nanowire includes n-type dopant to form a p-n junction in said diamond nanowire.

21. The method of claim 19 wherein one of said first and third layers includes p-type dopant and the other of said first and third layers includes n-type dopant.

22. The method of claim 19 further comprising polishing said second layer including said area of said of said first hole after said depositing of said diamond and before said forming of said third layer.

23. A method of forming a light source, said method comprising:
forming a first plurality of substantially parallel grooves in a first substrate layer;
depositing diamond into said first plurality of grooves to form a first plurality of diamond nanowires;
forming a second plurality of substantially parallel grooves in a second substrate layer disposed over said first substrate layer, said second plurality of grooves substantially perpendicular to said first plurality of grooves;
depositing diamond into said second plurality of grooves to form a second plurality of diamond nanowires; and
removing said first and second substrate layers, wherein said first and second pluralities of diamond nanowires emit light when coupled to a power source.

24. The method of claim 23 further comprising polishing said first plurality of diamond nanowires before said second substrate layer is in place.

25. The method of claim 23 wherein said first plurality of diamond nanowires is doped with p-type dopant and said second plurality of diamond nanowires is doped with n-type dopant to form p-n junctions where said diamond nanowires of said first plurality cross said diamond nanowires of said second plurality.
